(19) United States
(12) Patent Application Publication
(10) Pub. No.: US 2005/0024038 A1
(43) Pub. Date: Feb. 3, 2005

(54) Sampling circuit apparatus and method

(76) Inventors: John Santhoff, San Diego, CA (US); Steven A. Moore, Escondido, CA (US); Roger Rauvola, San Diego, CA (US); Charles Krinke, Irvine, CA (US)

Correspondence Address: PULSE-LINK, INC., 1969 KELLOGG AVENUE, CARLSBAD, CA, 92008, US

(21) Appl. No.: 10/633,608

(22) Filed: Jul. 31, 2003

(51) Int. Cl. G01R 19/18

(52) U.S. Cl. 324/118

(57) ABSTRACT

A system, method and apparatus for sampling an electromagnetic signal is provided. In one embodiment of the present invention, data is obtained from an electromagnetic signal by sampling the received signal and demodulating the signal without mixing the signal with a second electromagnetic signal. One feature of the present invention is that the signal may be sampled at a rate ranging between about 10 pico-seconds to about 500 pico-seconds. This Abstract is provided for the sole purpose of complying with the Abstract requirement rules that allow a reader to quickly ascertain the subject matter of the disclosure contained herein. This Abstract is submitted with the explicit understanding that it will not be used to interpret or to limit the scope or the meaning of the claims.

### FIELD OF THE INVENTION

The present invention generally relates to electrical circuits. More specifically, it relates to sampling and generating electromagnetic signals.

### BACKGROUND OF THE INVENTION

The wireless device industry has recently seen unprecedented growth. With the growth of this industry, communication between wireless devices has become increasingly important. There are a number of different technologies for inter-device communications. Radio frequency (RF) technology has been the predominant technology for wireless device communications. Electro-optical devices have also been used in wireless communications. However, electro-optical technology suffers from low ranges and a strict need for line of sight. RF devices therefore provide significant advantages over electro-optical devices.

Conventional RF technology employs continuous sine waves that are transmitted with data embedded in the modulation of the sine waves' amplitude or frequency. For example, a conventional cellular phone must operate at a particular frequency band of a particular width in the total frequency spectrum. Specifically, in the United States, the Federal Communications Commission has allocated cellular phone communications in the 800 to 900 MHz band. Generally, cellular phone operators divide the allocated band into 25 MHz portions, with selected portions transmitting cellular phone signals, and other portions receiving cellular phone signals.

Another type of inter-device communication technology is ultra-wideband (UWB). UWB wireless technology is fundamentally different from conventional forms of RF technology. UWB employs a “carrier free” architecture, which generally does not require the use of high frequency carrier generation hardware; carrier modulation hardware; frequency and phase discrimination hardware or other devices employed in conventional frequency domain (i.e., RF) communication systems.

A number of architectures for use of ultra-wideband communications have been suggested. In one approach, the frequency spectrum allocated to UWB communications devices is partitioned into discrete bands. Modulation techniques and wireless channelization schemes can then be designed around a UWB device operating within one or more of these sub-bands. Alternatively, a UWB communications device may occupy all or substantially all of the entire allocated spectrum.

Regardless of the amount of spectrum employed, most UWB communication devices may then use a modulation technique. For example, a UWB device may generate UWB pulses at specific amplitudes and or phases. All of these approaches require a UWB device to generate specific types of pulses, or pulse morphology, to conform to the desired architecture, or modulation technique.

Therefore, there exists a need for an electronic circuit architecture capable of operating in both narrowband and ultra-wideband communications technologies.

### SUMMARY OF THE INVENTION

The present invention provides circuits, systems and methods for constructing and using an electronic circuit. In one embodiment, the electronic circuit may be employed as a software definable radio receiver. In this embodiment, a software controllable sampler samples an electronic communication signal at extremely short time intervals. The samples may then be combined to form a received communication signal.

One feature of the present invention is to provide demodulation and data recovery of a wide range of communication signals, such as conventional sinusoidal waveform signals, as well as ultra-wideband signals. An associated feature of the present invention is that a device employing the present invention may receive one form of communication technology (sinusoidal waveform signals, for example) and transmit using another form of communication technology (ultra-wideband, for example).

Another embodiment of the present invention provides a method of maintaining time synchronization throughout extended time periods by sampling the electromagnetic signal(s) and adjusting a time reference based on the samples.

These and other features and advantages of the present invention will be appreciated from review of the following detailed description of the invention, along with the accompanying figures in which like reference numerals refer to like parts throughout.

### BRIEF DESCRIPTION OF THE DRAWING

FIG. 1 is an illustration of different communication methods;

FIG. 2 is an illustration of two ultra-wideband pulses;

FIG. 3 shows a schematic diagram of a programmable pulse generator constructed according to one embodiment of the present invention;

FIG. 4 shows a schematic diagram of a programmable pulse generator employing a demultiplexer constructed according to another embodiment of the present invention;

FIG. 5 shows a schematic diagram of a programmable pulse generator constructed according to yet another embodiment of the present invention;

FIG. 6 shows a schematic diagram of a programmable pulse generator constructed according to another embodiment of the present invention;

FIG. 7 shows a schematic diagram of a programmable pulse generator constructed according to another embodiment of the present invention;

FIG. 8 shows a schematic diagram of two series-connected arrays of pulse generation cells constructed according to one embodiment of the present invention;

FIG. 9 shows a schematic diagram of a two parallel-connected arrays of pulse generation cells constructed according to another embodiment of the present invention;

FIG. 10 shows a schematic diagram of a parallel-connected cell arrays with an arithmetic combining circuit constructed according to one embodiment of the present invention;

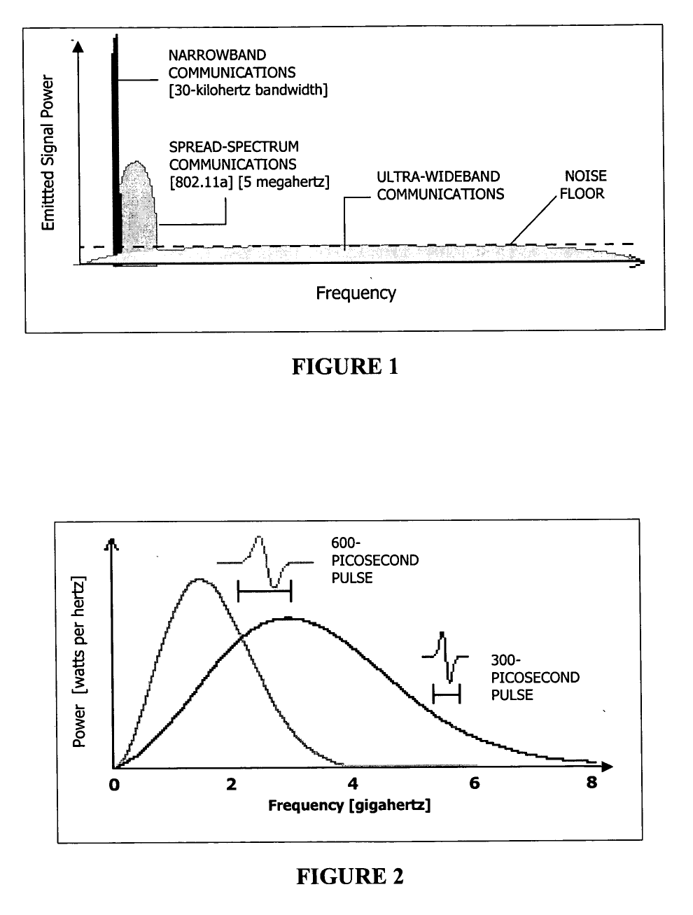

FIG. 1 shows one aggregate output of the pulse generation cells and/or arrays of the present invention arranged to form a electromagnetic waveform;

FIG. 12 shows different electromagnetic pulses employed in a multi-band ultra-wideband communication system;

FIG. 13 shows the frequency space occupied by the electromagnetic pulses in FIG. 12;

FIG. 14 shows different electromagnetic pulses formed by the electromagnetic pulses generation cells and/or arrays of the present invention;

FIG. 15 shows drift correction of a master time reference according to one embodiment of the present invention; and

FIG. 16. a electronic sampling circuit constructed according to one embodiment of the present invention.

It will be recognized that some or all of the Figures are schematic representations for purposes of illustration and do not necessarily depict the actual relative sizes or locations of the elements shown.

### DETAILED DESCRIPTION OF THE INVENTION

In the following paragraphs, the present invention will be described in detail by way of example with reference to the attached drawings. Throughout this description, the preferred embodiment and examples shown should be considered as exemplars, rather than as limitations on the present invention. As used herein, the “present invention” refers to any one of the embodiments of the invention described herein, and any equivalents. Furthermore, reference to various feature(s) of the “present invention” throughout this document does not mean that all claimed embodiments or methods must include the referenced feature(s).

There are many useful applications for extremely short duration pulses of electromagnetic energy. For example, in RADAR and other imaging applications short electromagnetic pulse durations can improve the resolution capability of the system. In ultra-wideband communications extremely short duration pulses are desirable as well.

The present invention provides an apparatus, method and system for electromagnetic pulse generation having extremely short duration. In addition, these same electromagnetic pulse generation apparatus may be modified to function as extremely fast sampling circuits, or cells. By sampling a received signal at an extremely fast rate, embodiments of the present invention may function as a receiver, and software defined radio transmitter.

In one embodiment of the present invention, a number of extremely short duration pulse generation cells are aggregated into an array. The aggregation may involve serial aggregation of control inputs, serial aggregation of pulse generation cell outputs, as well as parallel aggregation of both control inputs and pulse generation cell outputs. The data inputs, control inputs, and the on/off state of the current sources may be under digital computer software control through the use of a microprocessor or a finite state machine.

Conventional radio frequency technology employs continuous sine waves that are transmitted with data embedded in the modulation of the sine waves' amplitude or frequency. For example, a conventional cellular phone must operate at a particular frequency band of a particular width in the total frequency spectrum. Specifically, in the United States, the Federal Communications Commission has allocated cellular phone communications in the 800 to 900 MHz band. Cellular phone operators use 25 MHz of the allocated band to transmit cellular phone signals, and another 25 MHz of the allocated band to receive cellular phone signals.

Another example of a conventional radio frequency technology is illustrated in FIG. 1. 802.11a, a wireless local area network (LAN) protocol, transmits radio frequency signals at a 5 GHz center frequency, with a radio frequency spread of about 5 MHz.

In contrast to conventional “carrier wave” communications, another type of communication technology is emerging. Known as ultra-wideband (UWB), or impulse radio, it employs pulses of electromagnetic energy that are emitted at nanosecond or picosecond intervals (generally tens of picoseconds to a few nanoseconds in duration). For this reason, ultra-wideband is often called “impulse radio.” Because the excitation pulse is not a modulated waveform, UWB has also been termed “carrier-free” in that no apparent carrier frequency is evident in the radio frequency (RF) spectrum. That is, the UWB pulses are transmitted without modulation onto a sine wave carrier frequency, in contrast with conventional radio frequency technology. Ultra-wideband requires neither an assigned frequency, a power amplifier, high frequency carrier generation hardware, carrier modulation hardware, stabilizers, frequency and phase discrimination hardware or other devices employed in conventional frequency domain communication systems.

Referring to FIG. 2, an ultra-wideband (UWB) pulse may have a 1.8 GHz center frequency, with a frequency spread of approximately 3.2 GHz, which illustrates two typical UWB pulses. FIG. 2 illustrates that the narrower the UWB pulse in time, the broader the spread of its frequency spectrum. This is because frequency is inversely proportional to the time duration of the pulse. A 600-picosecond UWB pulse can have about a 1.8 GHz center frequency, with a frequency spread of approximately 1.6 GHz. And a 300-picosecond UWB pulse can have about a 3 GHz center frequency, with a frequency spread of approximately 3.2 GHz. And, a 50-picosecond UWB pulse can have about a 10 GHz center frequency, with a frequency spread of approximately 20 GHz. As mentioned above, the present invention is capable of producing extremely short duration electromagnetic pulses. For example, the present invention may produce electromagnetic pulses having a duration of as little as 1 picosecond.

Thus, UWB pulses generally do not operate within a specific frequency, as shown in FIG. 1. And because UWB pulses are spread across an extremely wide frequency range, UWB communication systems allow communications at very high data rates, such as 100 megabits per second or greater.

Further details of UWB technology are disclosed in U.S. Pat. No. 3,728,632 (in the name of Gerald F. Ross, and titled: Transmission and Reception System for Generating and Receiving Base-Band Duration Pulse Signals without Distortion for Short Base-Band Pulse Communication System), which is referred to and incorporated herein in its entirety by this reference.

Also, because the UWB pulse is spread across an extremely wide frequency range, the power sampled at a single, or specific frequency is very low. For example, a UWB one-watt signal of one nano-second duration spreads the one-watt over the entire frequency occupied by the pulse. At any single frequency, such as a cellular phone carrier frequency, the UWB pulse power present is one nano-watt (for a frequency band of 1 GHz). This is well within the noise floor of any cellular phone system and therefore does not interfere with the demodulation and recovery of the original cellular phone signals. Generally, the UWB pulses are transmitted at relatively low power (when sampled at a single, or specific frequency), for example, at less than −30 power decibels to −60 power decibels, which minimizes interference with conventional radio frequencies.

As described above, conventional wireless devices communicate with Radio Frequency (RF) energy. Conventional technologies for RF communications employ RF carrier waves. Data is modulated onto the carrier wave, amplified and transmitted from a RF device. A second RF wireless device receives the carrier wave, amplifies the wave, and demodulates the data. RF communications suffer from fading, multi-path interference, and channel attenuation. Since RF energy strength is proportional to the inverse of the transmitted distance squared, the quality of RF wireless communication is dependent on the relative location of the RF devices that are communicating. Atmospheric conditions, terrain, natural and man-made objects can additionally degrade the received signal strength of RF communications

One feature of the present invention is that with extremely short electromagnetic pulse generation capability, software-defined radio becomes feasible. That is, a conventional radio transmitter generally comprises a carrier-wave generator constructed to transmit a specific radio frequency, a device for modulating the carrier wave in accordance with information to be broadcast, amplifiers and an aerial system. This conventional radio transmitter only transmits at a specific frequency.

Software-defined radio is communication in which electromagnetic pulses, or conventional sine waveforms are generated, modulated, and decoded only by computer software. This allows a single computer-controlled receiver, transmitter or transceiver to interface and operate with a variety of communication services that use different frequencies, modulation methods and/or protocols. Changing the frequency, modulation method and/or protocol only requires using a different computer software program. Thus, software-defined radio is much more economical to manufacture, package, and produce.

Another embodiment of the present invention provides a method of maintaining signal time synchronization throughout extended time periods by sampling the electromagnetic signal(s) and adjusting a time reference based on the samples. This reduces, or eliminates, the dependency on phase locked loop circuits and the increased overhead of re-synchronization.

One feature of the present invention is that a group of short duration pulses of electromagnetic energy can be aggregated, or “stacked-up” to form a conventional radio frequency signal. A communication signal sampling theorem states that a signal must be sampled at twice the highest frequency component to be reliably recovered. This signal sampling theorem is generally known as either the Nyquist sampling theorem or the Shannon sampling theorem.

One corollary of this sampling theorem is that electromagnetic pulse generation systems can be used to represent, or simulate, continuous waveform signals if the time resolution, or duration of the pulses is such that the inverse of resolution is at least twice the highest frequency component in the desired waveform. For example, to aggregate a pulsed signal to represent cellular communications at 900 MHz would require at a minimum a 555 pico-second pulse duration. To replicate a 802.11(a) (i.e., BLUETOOTH) waveform would require pulse durations of 100 pico-seconds or less since the center frequency assigned to that communications technology is approximately 5 GHz. Additionally, to represent some conventional signal modulation techniques, the amplitude of the carrier waveform must also be reliably constructed. Therefore, re-creation, or simulation, of an amplitude modulated waveform may require the capability to produce extremely short duration pulses while controlling the amplitude of the pulses.

One capability envisioned by the present invention is a single mobile, or fixed, wireless device that can switch between various wireless, or wire communication technologies and standards. By way of example and not limitation, a device constructed according to the present invention may communicate with BLUETOOTH, WiFi, UWB, CDMA, GSM, PCS and a host of other communication technologies by employing a software-defined radio. One feature of the present invention is the generation and aggregation of extremely short duration electromagnetic pulses into waveforms that simulate a wide range of wireless communication technologies.

Wireless communication technologies may use a number of modulation techniques to impart data to the signal prior to transmission. Most of these modulation techniques are imparted to an existing carrier signal that changes properties based on the data. For example, in phase modulation schemes the phase of a carrier waveform is shifted in increments depending of the data to be imparted. In Amplitude Modulation (AM) the amplitude of the carrier signal is varied by the data to be carried. In Orthogonal Frequency Division Modulation (OFDM) data is modulated onto a set of orthogonal carriers prior to transmission. Since the carriers are selected to be orthogonal, there is minimal interference between the resultant modulated signals.

Ultra-wideband (UWB) pulse modulation techniques enable a single representative data symbol to represent a plurality of binary digits, or bits. This has the obvious advantage of increasing the data rate in a communication system. A few examples of UWB modulation include Pulse Width Modulation (PWM), Pulse Amplitude Modulation (PAM), and Pulse Position Modulation (PPM). In PWM, a series of pre-defined UWB pulse widths are used to represent different sets of bits. For example, in a system employing 8 different UWB pulse widths, each symbol could represent one of 8 combinations. This symbol would carry 3 bits of information. In PAM, pre-defined UWB pulse amplitudes are used to represent different sets of bits. A system employing PAM16 would have 16 pre-defined UWB pulse amplitudes. This system would be able to carry 4 bits of information per symbol. In a PPM system, pre-defined positions within an UWB pulse timeslot are used to carry a set of bits. A system employing PPM16 would be capable of carrying 4 bits of information per symbol. Additional UWB pulse modulation techniques, not listed, may be employed by the present invention.

One feature of the present invention is that it allows a computer software control unit to select appropriate electromagnetic pulse generation cells in such a way as to generate a carrier signal that is already modulated to reflect the desired data to be sent. This can reduce the complexity and expense of communication device design in that modulation hardware is no longer necessary to impart data onto the carrier signal.

An additional feature of the present invention is that it may act as a “bridge” between different communication technologies. By way of example and not limitation, a narrowband PCS signal may be received at a frequency of approximately 1.9 GHz. A communication device employing the present invention may re-transmit the PCS signal by transmitting a 900 MHz signal that conforms with a CDMA communication system. Alternatively, the re-transmission may employ a UWB wireless link using UWB communication methods described above. The UWB wireless link may transmit across a frequency band extending from about 3.1 GHz to about 10.6 GHz.

The present invention provides a computer software controllable waveform generator for use in wireless, or wire communication that aggregates a number of extremely short duration pulses. Further details of extremely short electromagnetic pulse generation techniques and methods are discussed in detail in METHODS, APPARATUSES, AND SYSTEMS FOR SAMPLING OR PULSE GENERATION, U.S. Pat. No. 6,433,720, issued to Libove et al., on Aug. 13, 2002, which is incorporated herein by reference in its entirety.

The electromagnetic pulse generation cell(s) employed in the present invention may have one, or more software controllable interfaces. In one embodiment, the software control interface employs at least one digital to analog conversion (DAC) circuit. In this embodiment, a DAC may be used to provide the control signal of the pulse generation cell(s). Alternatively, a DAC may be used to deactivate a switch placed inline with the current source of each pulse generation cell effectively shutting down unused pulse generation cell(s). Alternatively, a DAC may be used by a software control unit to control the flow of data to the input stage of each pulse generation cell. A still further use of a software controlled DAC would provide control signals to the aggregation or combining circuit that combines the output of serial and/or parallel arrays of pulse generation cells. Additionally a DAC may be used to provide threshold voltage levels in the pulse generation cell(s).

In another embodiment of the present invention, a computer microprocessor or alternatively a finite state machine, may send signals directly to the above mentioned inputs without the use of DAC hardware. A finite state machine is any device that stores the status of something at a given time and can operate on input to change the status and/or cause an action or output to take place for any given change. Thus, at any given moment in time, a computer system can be seen as a set of states and each program in it as a finite state machine. For example, a finite state machine may be a hardware implementation of computer logic, or software.

As conceived herein, electromagnetic pulse generation cells may be configured in a number of ways. In one embodiment, pulse generation cells are connected in series, relative to the control input, with a single set of output terminals to form a Serial Array Single Output (SASO). In this embodiment delay lines may be used to set the time of pulse generation of each cell relative to the first cell's output. Generally, a delay line is a device that introduces a time lag in a signal. The time lag is usually calculated as the time required for the signal to pass though the delay line device, minus the time necessary for the signal to traverse the same distance without the delay line.

In this configuration, a transition in a control signal generates a pulse proportional to the data input on the first cell. The control signal then passes through a delay line to a second cell and causes a pulse to be generated in the output proportional to the data input on the second cell. The second pulse is delayed in time relative to the first by the delay in the control signal. Subsequent stages in the SASO can be further delayed providing pulse outputs at their appropriate time interval. This configuration may be used without delay lines causing the pulses produced by each individual cell to be summed at the output terminals.

Another configuration of pulse generation cells involves connecting in series, relative to the control input, a number of cells where each cell has output terminals. In this configuration, a serial input multiple output (SAMO), can be implemented with or without delay lines to provide simultaneous outputs or outputs that are temporally spaced due to the delay in the control transition. In this configuration, the outputs may be summed at a common node, or provided to a mixing circuit such as a Gilbert Multiplier, or a Half Gilbert Multiplier, and the product is then taken.

In a still further configuration, a combination of electromagnetic pulse generation cells may be connected in parallel, relative to the control inputs. In this configuration, each pulse generation cell may receive a different control signal. In this configuration, the timing of the control inputs can directly control generation and temporal spacing of the pulses. The cells may be configured to have a single output (PASO) or multiple outputs (PAMO).

In another configuration, two-dimensional arrays of SASO, SAMO, PASO, and PAMO arrays may be connected serially or in parallel to provide additional functionality.

In conventional communication technologies a carrier waveform is generated then data is modulated onto the waveform. For example, most conventional systems use a local oscillator to provide a sine wave carrier, and then data is modulated onto the carrier, or waveform. In some forms of ultra-wideband communications, a pulse is generated then filtered or mixed to achieve a desired center frequency. In one embodiment of the present invention, the pulse generation cells are configured to produce waveforms at the desired center frequency, and are also configured to represent data in its modulated form. This reduces the complexity and expense of the transmitter design by eliminating modulation and mixing hardware and potentially eliminating the need for bandpass filters.

By controlling the shape of a generated waveform to the tens of picoseconds, it is possible to limit the frequency content of the resultant waveform. One feature of the present invention provides a waveform generator for electronic communication systems that complies with FCC emission limit regulations without employing bandpass filters to reject out-of-band emissions.

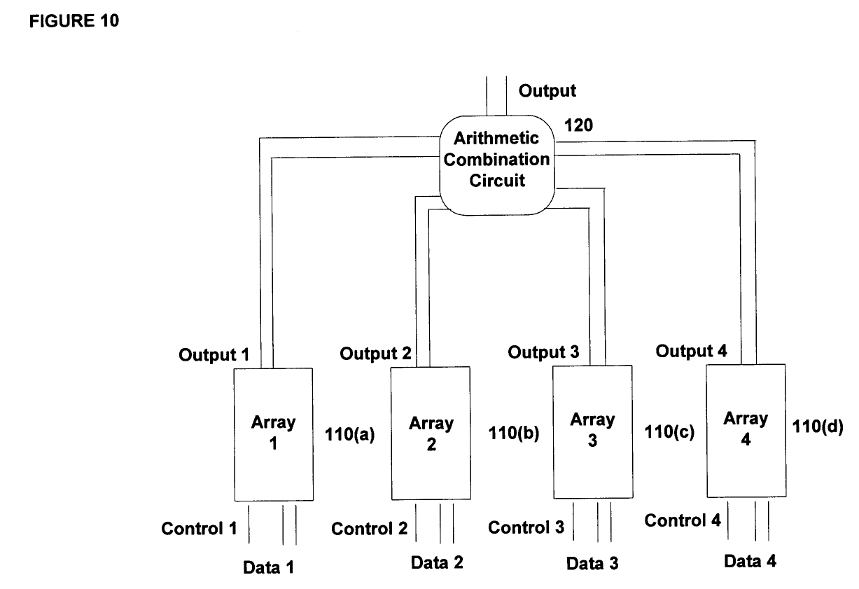

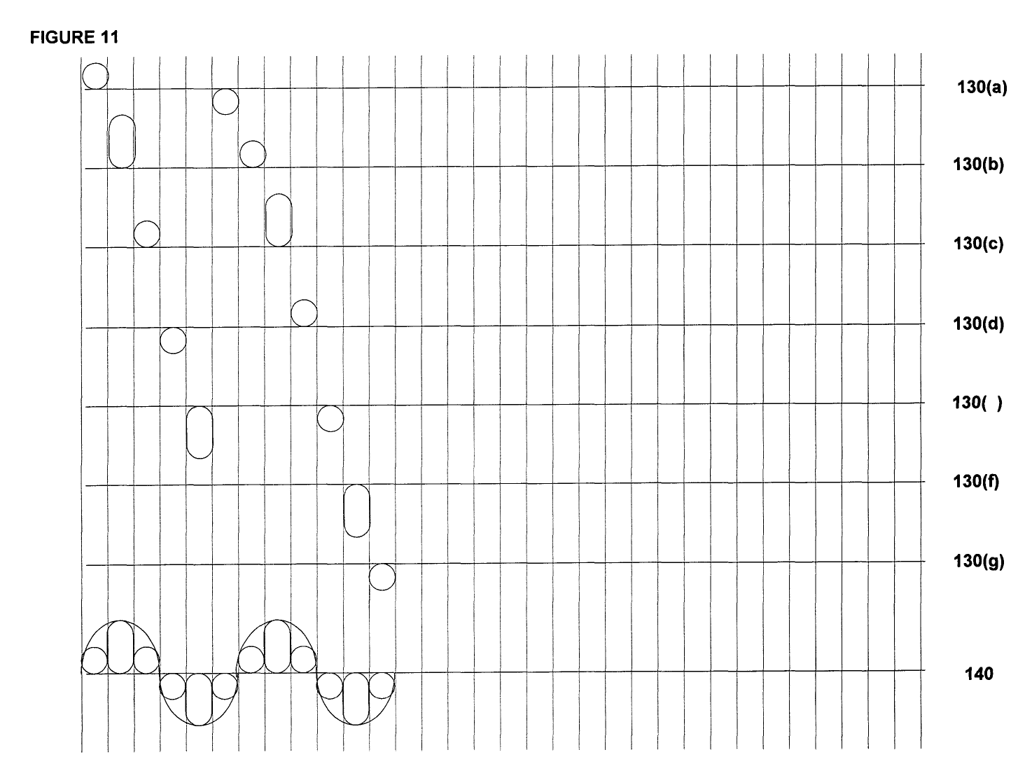

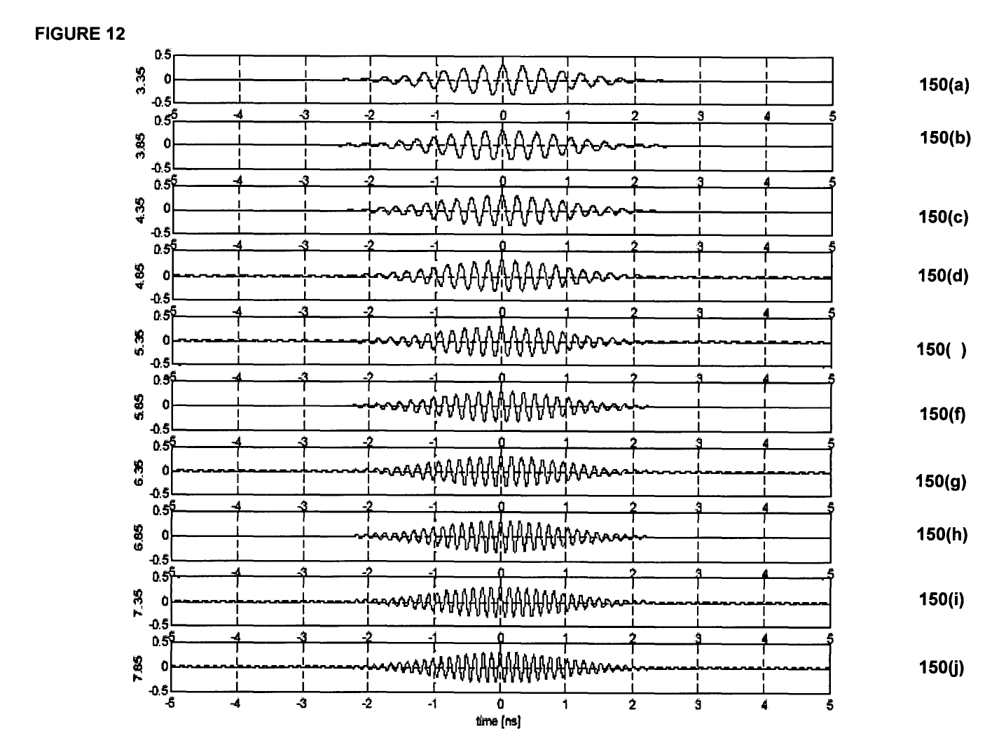

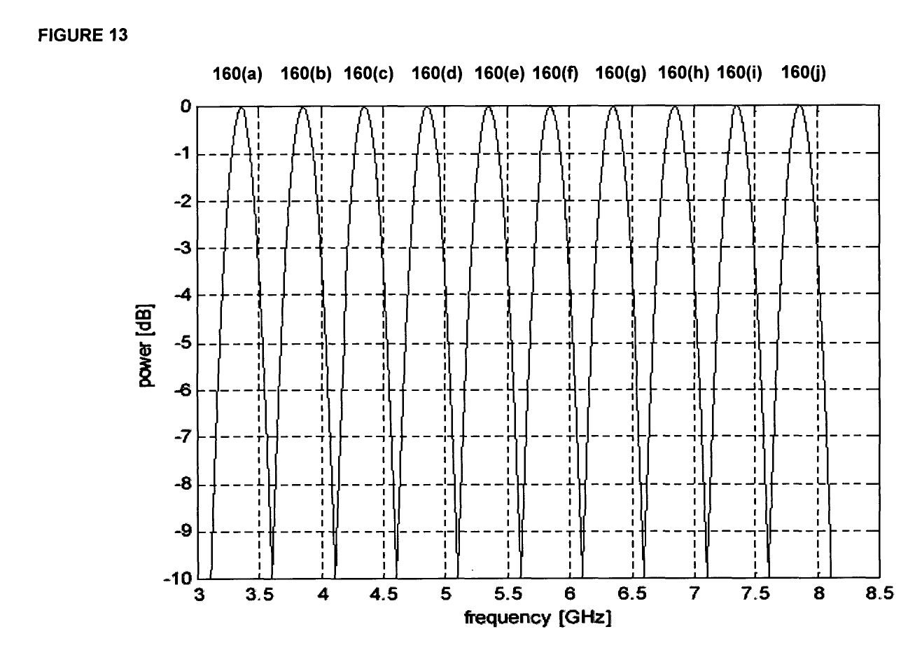

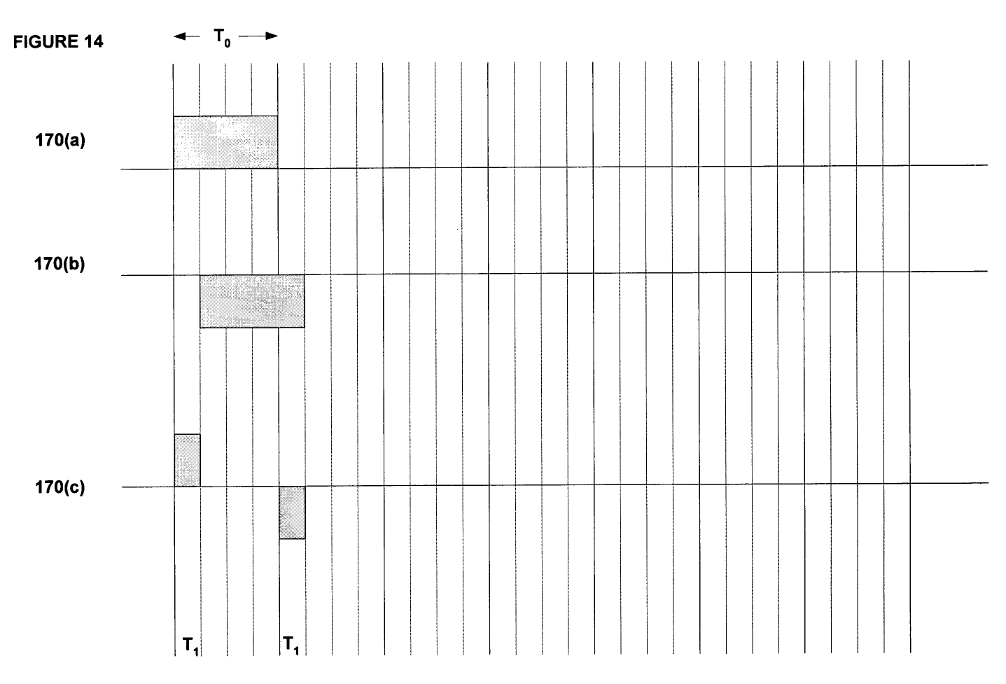

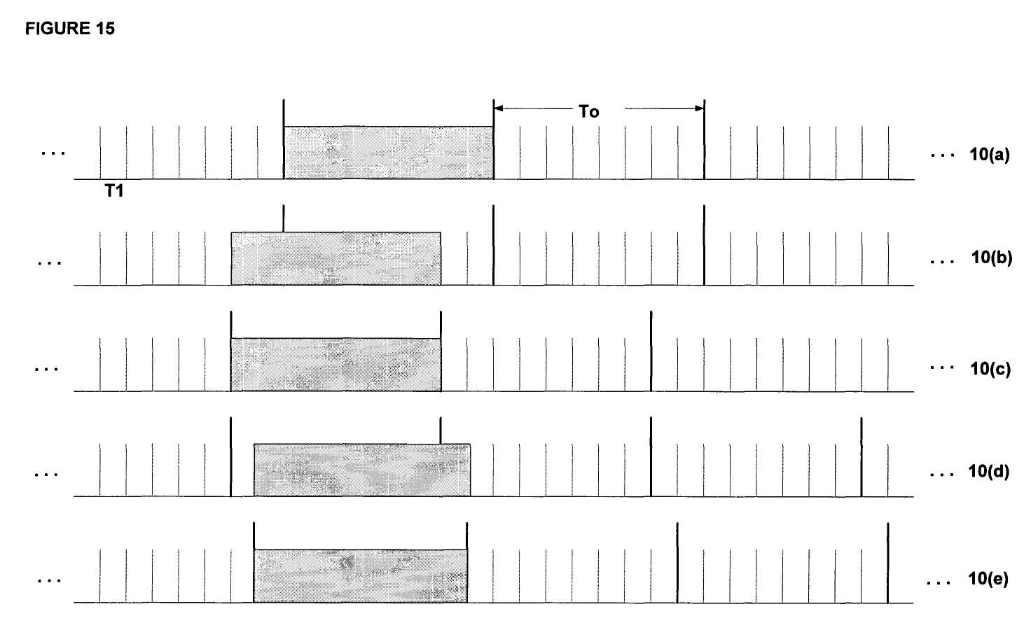

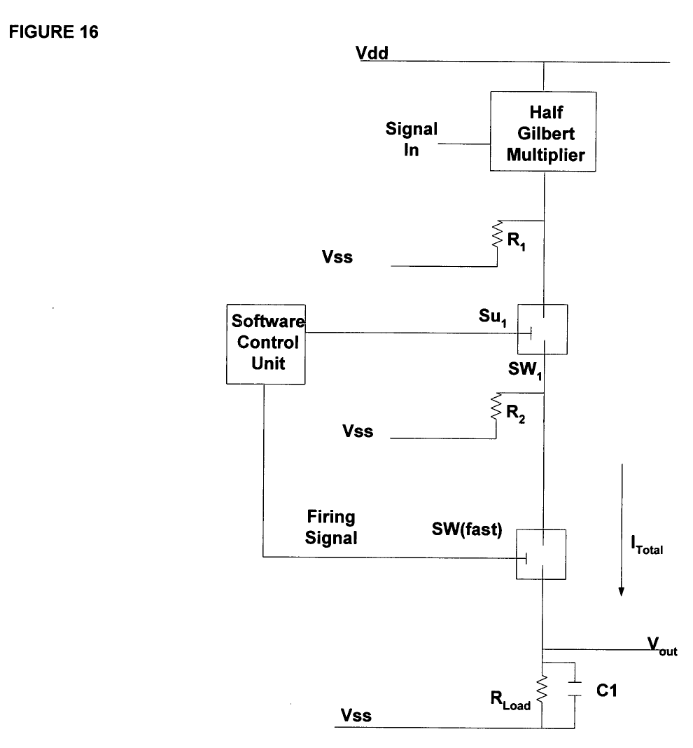

Another feature of the present invention provides a waveform generator that may be software controlled to produce ultra-wideband (UWB) pulses compliant with both single-band and multi-band UWB systems. Current Federal Communications Commission (FCC) regulations establish “spectrum masks” that limit outdoor ultra-wideband emissions to −41 dBm between 3.1 GHz and 10.6 GHz. A single-band ultra-wideband (UWB) communication system may emit UWB pulses having a frequency spread that would extend from about 3.1 GHz to about 10.6 GHz. A multi-band UWB communication system may break-up the available frequency and emit UWB pulses in discrete frequency bands, for example, 200 MHz bands, 400 MHz bands, or 600 MHz bands. It will be appreciated that other frequency band allocations may be employed. An example of a possible multi-band UWB communication system is illustrated in FIG. 10.

Additionally, the present invention allows a communication device to bridge, or convert data received from a single-band UWB communication system to a multi-band communication system and vice-versa, as well as bridging data between conventional carrier wave communication technologies as described above, and UWB communication technologies.

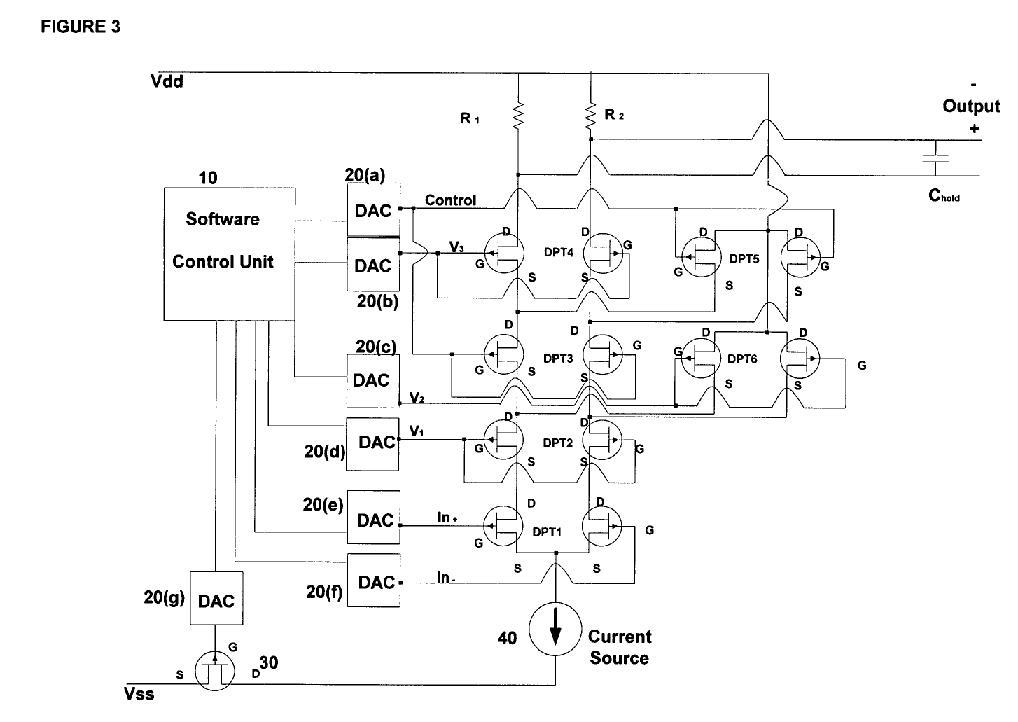

Referring now to FIG. 3, an electromagnetic pulse generation cell constructed according to one embodiment of the present invention is illustrated. This electromagnetic pulse generation cell, as well as the other embodiment electromagnetic pulse generation cells described herein, may be employed as extremely fast electromagnetic sampling cells, or circuits as well. For example, a signal to be sampled is superimposed on the inputs to the first differentially paired transistors (DPTs), described below. When the circuit, or cell, is in the active mode (that is, when the DPTs are in the triode region between on and off) the output pulse is proportional to the signal present on the inputs. In this manner these circuits, or cells, are capable of sampling an incoming electromagnetic signal at a time resolution equivalent to the pulse generation aperture.

For example, a number of communications systems employ some form of signal amplitude modulation (AM). There are various approaches to demodulate AM signals. In one approach, an AM signal is mixed with a carrier at the same frequency. The AM signal can be represented by y(t)=m(t)cos(ω_{c}t), where m(t) is the data present on carrier cos(ω_{c}). Mixing this signal with a carrier at (ω_{c}), yields the following:

$$\begin{matrix}x ( t ) = y ( t ) cos ( {ω}_{c} t ) \\ x ( t ) = m ( t ) cos ( {ω}_{c} t ) cos ( {ω}_{c} t ) \\ x ( t ) = m ( t ) {cos}^{2} ( {ω}_{c} t ) \\ x ( t ) = \frac{1}{2} m ( t ) + \frac{1}{2} cos ( 2 {ω}_{c} t )\end{matrix}$$

The resultant signal is then filtered with a lowpass filter that recovers the

$$\frac{1}{2} m ( t )$$

component of the signal. Another demodulation method employs an envelope detector and an analog to digital converter.

In contrast, the present invention uses extremely fast sampling cells, as described below, whose output is proportional to the amplitude of the signal received. Direct demodulation of AM signals is therefore possible without the use of mixers or envelope detectors that are traditionally used.

Similarly, in frequency modulated (FM) and phase modulated communications systems the data is carried in the instantaneous frequency of the signal. Demodulation of these two types of signals is similar in nature. Demodulation of FM is usually accomplished using a phase locked loop (PLL) circuit and mixing circuits. The present invention, sampling at extremely fast rates, can detect variations in phase and frequency directly from the output of the sampling cells by a mathematical combining circuit.

Referring now to FIG. 3, an electromagnetic pulse generation, or sampling cell constructed according to one embodiment of the present invention is illustrated. Data of interest is input to the gate terminals (G) of the differential input stage DPT 1. DPT 1 has its source terminals (S) connected to the current source. The drain terminals (D) of DPT 1 are connected to the source terminals (S) of DPT 2. The gate terminals (G) of DPT 2 are connected to the output of the Inverter. The Inverter may be a phase inverter, a digital inverter, or any other suitable inverter.

The drain terminals (D) of DPT 2 are connected to the source terminals (S) of DPT 3. The gate terminals (G) of DPT 3 are connected to the output of a delay element D1. As discussed above, the delay element is a device that introduces a time lag in a signal. The time lag is usually calculated as the time required for the signal to pass though the delay line device, minus the time necessary for the signal to traverse the same distance without the delay element.

The drain terminals (D) of DPT 3 are connected to resistive elements R1 and R2. Resistive elements R3 and R4 are connected to a voltage source such as Vdd and to the source terminals (S) of DPT 3.

A Control signal is connected to the input of delay D1 and to the input of the Inverter. The power and ground connections of the Inverter can be connected to Vdd1 and Vss respectively, or alternatively to other voltage potentials not shown. All of the signals may be software controlled by the use of a software control unit (SCU), and/or optional digital to analog converters (DACs) not shown. DAC circuits may comprise multi-bit DAC circuits or alternatively be replaced by voltage divider circuits configured to provide specific voltage levels used by the pulse generation cell.

The Control may comprise a SCU or one or more DACs, and generate the control signals. The delay element D1 is calculated to delay the Control signal from reaching the gate terminals (G) of DPT 3 until the output of the Inverter reaches the gate terminals (G) of DPT 2. Alternatively, the Inverter may be connected to a voltage level distinct from Vdd1.

The function of resistive elements R3 and R4 is to provide appropriate biasing to the circuit. For example, as is generally known, biasing is used to establish a predetermined threshold or operating point. Other methods of biasing are known in the art and may be used to provide this function.

The operation of the electromagnetic pulse generation cell illustrated in FIG. 3 will now be explained. When Control is at a low voltage level, DPT 3 is turned “off” and the output of the Inverter turns “on” DPT 2. When Control is at a high voltage level, DPT 3 is turned “on” and the output of the Inverter turns “off” DPT 2. During the transition of Control from a first voltage level to a second voltage level, both DPT 3 and DPT 2 allow current to flow. Because the amount of current is dependent on the voltage levels at the input terminals of DPT 1, the output signal will be proportional to the voltage present at those terminals.

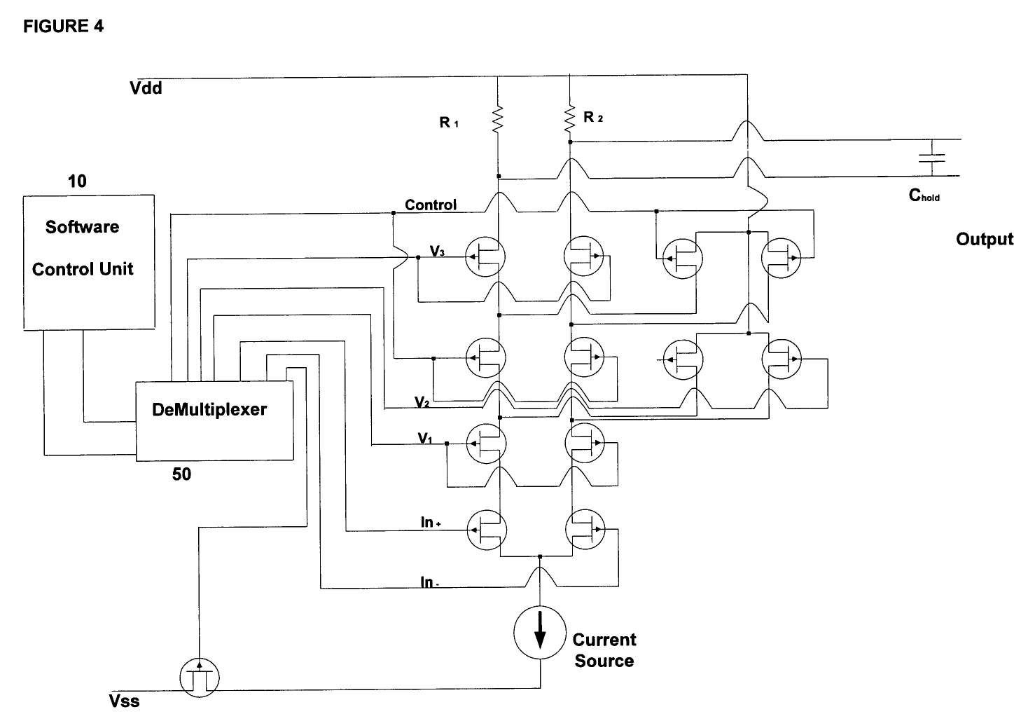

Referring now to FIG. 4, an alternative embodiment electromagnetic pulse generation cell, similar to the cell of FIG. 3 is illustrated. The pulse generation cell of FIG. 4 includes a demultiplexer. Another embodiment of an electromagnetic pulse generation cell may be configured as illustrated in FIG. 4, but may also include the DAC circuits 20(a-g) illustrated in FIG. 3. The embodiment illustrated in FIG. 4 is essentially constructed as illustrated and described above in connection with FIG. 3, with the exception that all signals from the SCU are sent to demultiplexer 50. Demultiplexer 50 is under the control of SCU 10. Control and data signals are sent to demultiplexer 50 from SCU 10. In this embodiment, the demultiplexer 50 routes the appropriate signals to the different parts of the pulse generation circuit illustrated in FIG. 4.

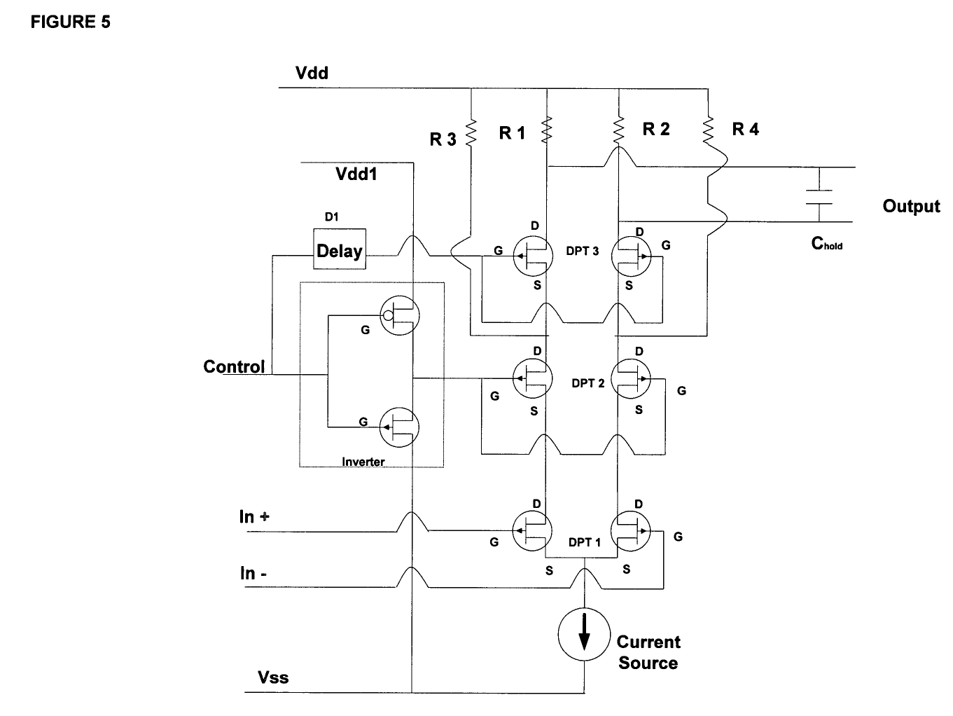

Referring now to FIG. 5, an electromagnetic pulse generation cell constructed according to one embodiment of the present invention is illustrated. Data is input to the gate terminals (G) of the differential input stage DPT 1. DPT 1 has its source terminals (S) connected to the current source. The drain terminals (D) of DPT 1 are connected to the source terminals (S) of DPT 2. The gate terminals (G) of DPT 2 are connected to the output of the Inverter. The Inverter may be a phase inverter, a digital inverter, or any other suitable inverter.

The drain terminals (D) of DPT 2 are connected to the source terminals (S) of DPT 3. The gate terminals (G) of DPT 3 are connected to the output of a delay element D1. As discussed above, the delay element is a device that introduces a time lag in a signal. The time lag is usually calculated as the time required for the signal to pass though the delay line device, minus the time necessary for the signal to traverse the same distance without the delay element.

The drain terminals (D) of DPT 3 are connected to resistive elements R1 and R2. Resistive elements R3 and R4 are connected to a voltage source such as Vdd and to the source terminals (S) of DPT 3.

A Control signal is connected to the input of delay D1 and to the input of the Inverter. The power and ground connections of the Inverter can be connected to Vdd1 and Vss respectively, or alternatively to other voltage potentials not shown. All of the signals may be software controlled by the use of a software control unit (SCU), and/or optional digital to analog converters (DACs) not shown. DAC circuits may comprise multi-bit DAC circuits or alternatively be replaced by voltage divider circuits configured to provide specific voltage levels used by the pulse generation cell.

The Control may comprise a SCU or one or more DACs, and generate the control signals. The delay element D1 is calculated to delay the Control signal from reaching the gate terminals (G) of DPT 3 until the output of the Inverter reaches the gate terminals (G) of DPT 2. Alternatively, the Inverter may be connected to a voltage level distinct from Vdd1.

The function of resistive elements R3 and R4 is to provide appropriate biasing to the circuit. For example, as is generally known, biasing is used to establish a predetermined threshold or operating point. Other methods of biasing are known in the art and may be used to provide this function.

The operation of the electromagnetic pulse generation cell illustrated in FIG. 5 will now be explained. When Control is at a low voltage level, DPT 3 is turned “off” and the output of the Inverter turns “on” DPT 2. When Control is at a high voltage level, DPT 3 is turned “on” and the output of the Inverter turns “off” DPT 2. During the transition of Control from a first voltage level to a second voltage level, both DPT 3 and DPT 2 allow current to flow. Because the amount of current is dependent on the voltage levels at the input terminals of DPT 1, the output signal will be proportional to the voltage present at those terminals.

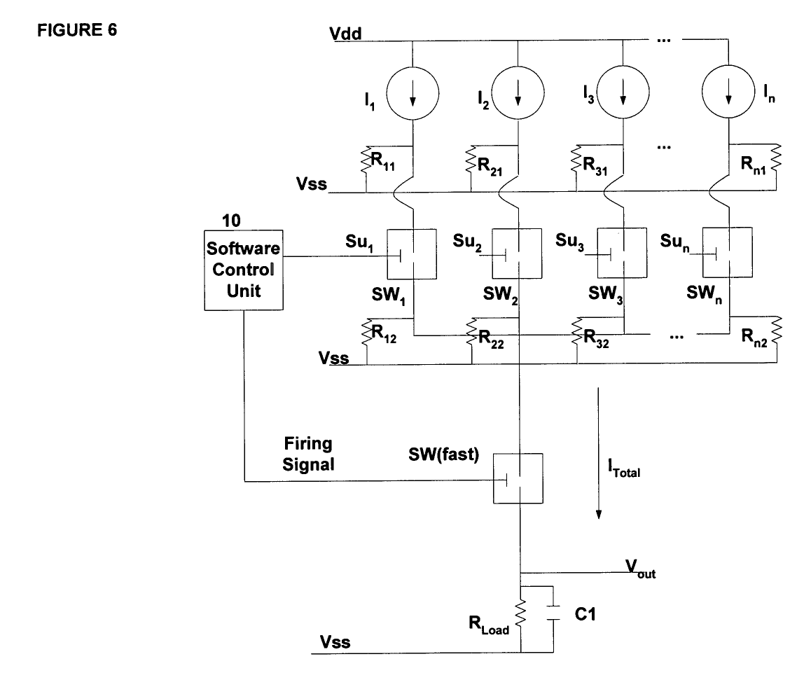

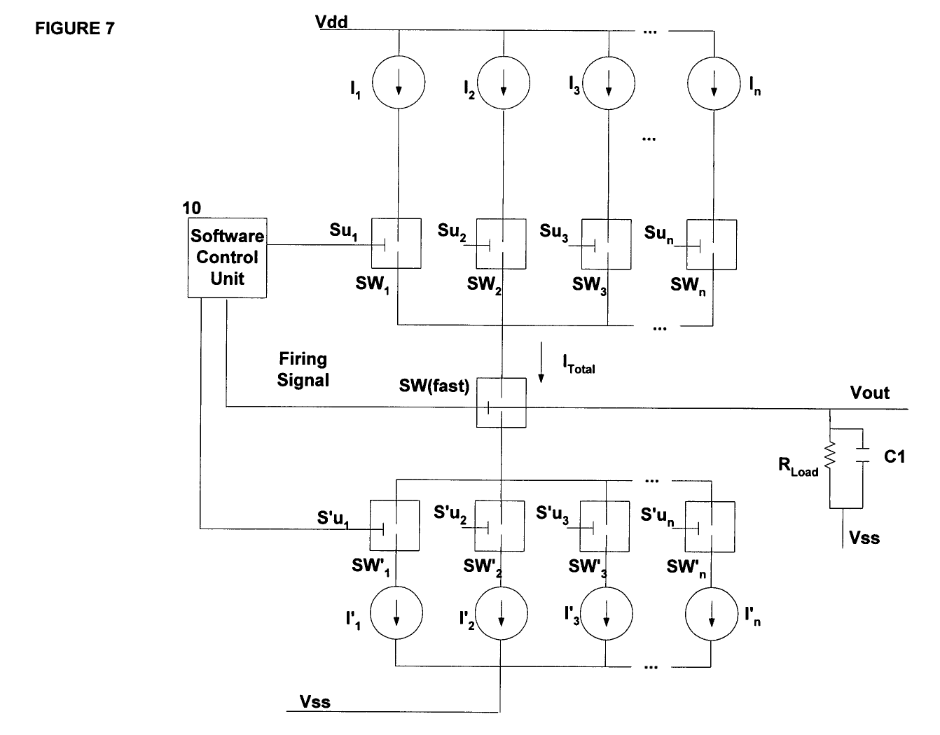

Referring now to FIGS. 6 and 7, electromagnetic pulse generation cells constructed according to other embodiments of the present invention are illustrated. In one embodiment of this architecture, a plurality of current sources I₁ through Iₙ provide current through resistive elements R₁₁ through Rₙ₁ when switches SW₁ through SWₙ are in the open position. This mode of operation ensures that the current sources I₁ through Iₙ remain turned-on prior to selection by software control unit (SCU) 10. SCU 10 is capable of providing a number of control signals to the cell. SCU 10 may comprise a microprocessor or alternatively may comprise a finite state machine capable of providing the necessary digital control signals to the various parts of the pulse generation cells illustrated in FIGS. 4 and 5.

SCU 10 provides set-up signals SU1 through SUn to switches SW₁ through SWₙ. Switches SW₁ through SWₙ are in either an open or a closed state depending on the set-up signals SU1 through SUn. Once selected R₁₂ through Rₙ₂ provide a path for currents I₁ through Iₙ prior to the Firing Signal becoming active. In this state, SCU 10 has selected which currents I₁ through Iₙ will pass through high-speed switch SW_{(fast)} when the Firing Signal is activated. Once the Firing Signal is activated by SCU 10, the Iₜₒₜₐₗ, the sum of the selected currents I₁ through Iₙ, conducts through high-speed switch SW_{(fast)} and develops a change in voltage Vₒᵤₜ.

In the electromagnetic pulse generation cell illustrated in FIG. 6, the current sources I₁ through Iₙ are mirror currents of a master current source. These mirror currents may be precisely controlled to be near duplicates of the master current source (not shown). Alternatively, a number of known techniques may be employed to divide or multiply the master current source (not shown) to obtain other current values. A number of devices may be used as selection switches, and include transistors, differential paired transistors (DPTs), and other suitable devices.

High-speed switch SW_{(fast)} may only allow current to pass when two or more switching elements, such as transistors, are in the triode region, and prevent current flow when at least one of the switching elements is saturated, or in an off state.

For example, when an inverter comprising at least two transistors is used for high-speed switch SW_{(fast)}, the switch SW_{(fast)} is in steady-state when one transistor is off and the other is on. The triode region (when both transistors are between on and off) that occurs when the transistors switch states provides a path for current flow. Specifically, the triode state occurs between when the first transistor is on and the second transistor is off, to when the first transistor is off and the second transistor is on. This triode region, between when the transistors switch states, provides a path for current flow.

In the first state, Vₒᵤₜ would approximate Vₛₛ since no current is flowing across the load. Likewise in the second state Vₒᵤₜ approximates Vₛₛ for the same reason. When SW_{(fast)} is switching states, current is allowed to flow across the load and an electromagnetic pulse is produced.

In an alternate embodiment of this extremely short duration electromagnetic pulse generation architecture, shown in FIG. 7, source currents I₁ through Iₙ, are duplicated as sink currents I′₁ through I′ₙ. Additionally, switches SW₁ through SWₙ are duplicated in the sink channel as SW′₁ through SW′ₙ. In this embodiment, SCU 10 provides set-up signals SU′1 through SU′n to switches SW′₁ through SW′ₙ ensuring the aggregate currents sourced from I₁ through Iₙ are sinked by I′₁ through I′ₙ. That is, I′₁ through I′ₙ provide a path to ground for I₁ through Iₙ.

The high-speed switch SW_{(fast)} can provide a higher impedance path for current when in the open state. When high-speed switch SW_{(fast)} receives a Firing Signal from SCU 10, it changes states and allows Iₜₒₜₐₗ, the sum of currents I₁ through Iₙ to flow to the load R_{load} and C₁.

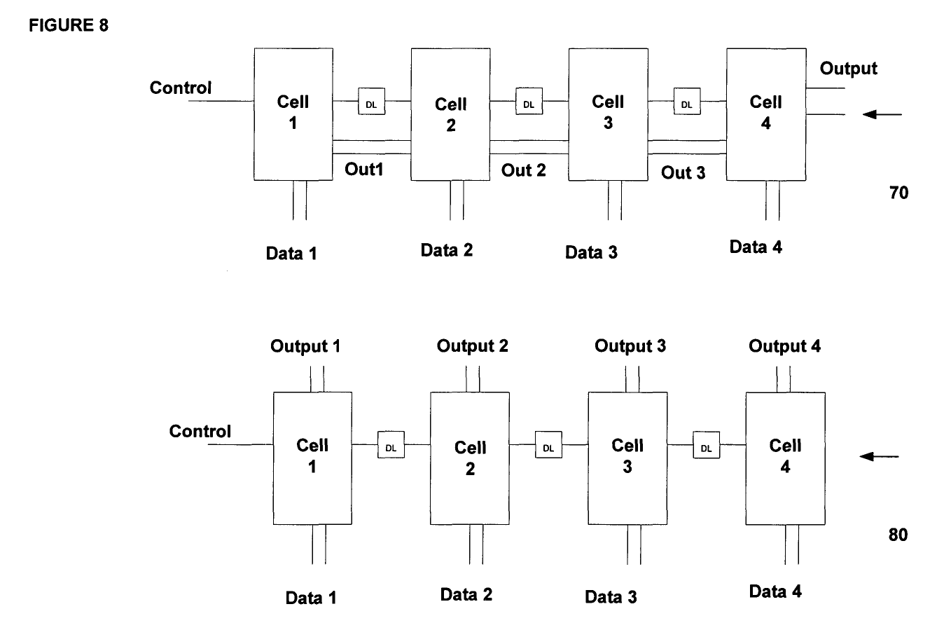

Referring to FIG. 8, two additional configurations of pulse generation cells constructed according to the present invention are illustrated. Each of Cell 1-4 represents any one of the pulse generation cells illustrated in FIGS. 3-7, or alternative embodiments thereof. It will be appreciated that any number of pulse generation cells may be employed by the present invention, with the four cells illustrated for drawing expediency. Cell array 90 is a Parallel Array Single Output (PASO). In this configuration, data 1-4 is input into each cell 1-4, and the control inputs 1-4 are individually input into each cell 1-4. The entire cell array 90 is configured to give a single differential output. Alternatively, cell array 100 is a Parallel Array Multiple Output array (PAMO). In this configuration, the control inputs 1-4 are individually input into each cell 1-4, but each cell has an independent output 1-4.

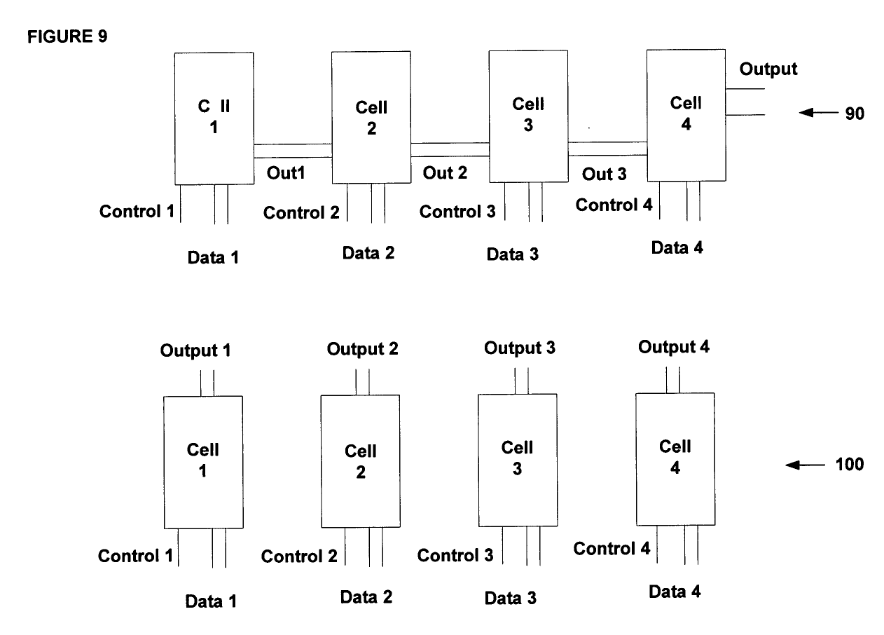

Referring to FIG. 9, two additional configurations of pulse generation cells constructed according to the present invention are illustrated. Each of Cell 1-4 represents any one of the pulse generation cells illustrated in FIGS. 3-7, or alternative embodiments thereof. It will be appreciated that any number of pulse generation cells may be employed by the present invention, with the four cells illustrated for drawing expediency. Cell array 90 is a Parallel Array Single Output (PASO). In this configuration, data 1-4 is input into each cell 1-4, and the control inputs 1-4 are individually input into each cell 1-4. The entire cell array 90 is configured to give a single differential output. Alternatively, cell array 100 is a Parallel Array Multiple Output array (PAMO). In this configuration, the control inputs 1-4 are individually input into each cell 1-4, but each cell has an independent output 1-4.

Referring to FIG. 10, an arithmetic combination circuit 120 is combined with a group of array elements 1-4. The output from the arithmetic combination circuit 120 may be used to produce any desired electromagnetic waveform. It will be appreciated that any number of array elements may be employed by the present invention, with the four array elements illustrated for drawing expediency. Array elements 110(a-d) are connected in parallel to Arithmetic Combination Circuit 120. The Array elements shown may comprise the cell arrays 70, 80, 90 and 100 (SASO, SAMO, PASO, and PAMO) as described above in connection with FIGS. 5-6. Any number of array elements may be used to produce a desired electromagnetic waveform. Data 1-4 is input into the array elements 1-4, and the outputs 1-4 of the array elements 110(a-d) are connected to arithmetic combination circuit 120. The arithmetic combination circuit 120 may comprise switching elements, summing circuits, inverting circuits, integrating and differentiating circuits, mixers, multipliers, and other suitable devices. Additionally, the arithmetic combination circuit 120 may be computer software controllable, and may or may not include DAC circuitry.

Referring to FIG. 10, an arithmetic combination circuit 120 is combined with a group of array elements 1-4. The output from the arithmetic combination circuit 120 may be used to produce any desired electromagnetic waveform. It will be appreciated that any number of array elements may be employed by the present invention, with the four array elements illustrated for drawing expediency. Array elements 110(a-d) are connected in parallel to Arithmetic Combination Circuit 120. The Array elements shown may comprise the cell arrays 70, 80, 90 and 100 (SASO, SAMO, PASO, and PAMO) as described above in connection with FIGS. 8-9. Any number of array elements may be used to produce a desired electromagnetic waveform. Data 1-4 is input into the array elements 1-4, and the outputs 1-4 of the array elements 110(a-d) are connected to arithmetic combination circuit 120. The arithmetic combination circuit 120 may comprise switching elements, summing circuits, inverting circuits, integrating and differentiating circuits, mixers, multipliers, and other suitable devices. Additionally, the arithmetic combination circuit 120 may be computer software controllable, and may or may not include DAC circuitry.

FIG. 11 illustrates an electromagnetic sine wave generated by the arithmetic aggregation of outputs from the cells 1-4 or arrays 1-4. In this example, the cell 1-4 or array 1-4 outputs 130(a-g) are summed to produce an electromagnetic sine wave as an output 140. Each output 130(a-g), corresponding to the outputs from the cells 1-4 or arrays 1-4, is independently controllable, as discussed above in connection with the operation of the cells 1-4 and array elements 1-4. Thus, any desired waveform, such as waveform 140, shown in FIG. 11, can be produced by the arithmetic combination circuit 120.

As also shown in FIG. 11, discrete pulses of electromagnetic energy can be output from the plurality of cells 1-4 or arrays 1-4. These individual outputs 103(a-g), can be employed individually, or aggregated for use in an ultra-wideband communication system, with discrete pulses ranging from about 1 pico-second to about 1 milli-second in duration.

FIGS. 12 and 13 illustrate electromagnetic pulses generated by the outputs from one or more cells 1-4 or arrays 1-4. In this example, the cell 1-4 or array 1-4 outputs are in the form of a plurality of pulses 150(a-j). Shown in FIG. 10, are the frequency spectra 160(a-j) corresponding to each of the pulses 150(a-j).

One feature of the present invention is that pulses 150 (a-j) having frequency spectra 160 (a-j) may be used in a multi-band ultra-wideband (UWB) communication system. For example, multi-band UWB systems usually fall into two architectures. The first architecture generates a electromagnetic pulse with a duration relating to the amount of frequency to be occupied by the band. The UWB pulse is then filtered with a bandpass filter that has a center frequency at the center of the frequency band to be occupied. When transmitted, the resultant pulse will occupy the appropriate amount of frequency around the center of the bandpass filters bandwidth.

A second multi-band UWB communication architecture involves generating a pulse with the appropriate bandwidth and mixing it with a carrier wave of the desired center frequency. The complexity of both architectures is significant.

In one embodiment of the present invention, multi-band UWB pulses are generated directly without the use of mixing circuits and bandpass filters. These pulse streams are generated directly, or are generated by the aggregation of pulse generation cells using the arithmetic combination circuit 120, shown in FIG. 10. Since the electromagnetic waveform generator herein described is controlled by computer software, it has the ability to quickly and easily switch between single-band UWB communication architectures and multi-band UWB communication architectures by generating pulses with characteristics suitable to each architecture. Additionally, the same electromagnetic waveform generator may be used to generate a wide range of conventional sine wave signals (140), as shown in FIG. 11 Referring specifically to FIG. 14, in another embodiment of the present invention narrow pulse widths can be obtained by initially generating pulses 170(a) and 170(b). The initial pulses 170(a) and 170(b) may have duration T₀. The Arithmetic Combination Circuit 120 is used to narrow the resulting pulses to duration T₁ by delaying pulse 170(b) and by amount T₁ and performing an arithmetic function, addition in the case shown, on the two pulses. The resultant pulses 170(c) have duration T₀. For example, the ultra-fast pulse generation cells herein described are capable of generating pulses with durations of 50 picoseconds or less. With the use of delay lines, pulse 170(b) can be delayed by 10 picoseconds relative to pulse 170(a). The sum of pulses 170(a) and 170(b) shown in 170(c) would then have a duration of 10 picoseconds.

Referring to FIG. 15, a method of synchronizing, or correcting a time reference according to one embodiment of the present invention is illustrated. Generally, conventional communication devices require the transmitter and the receiver to synchronize their time references, or master time references. Typically when the receiving device detects a time synchronization sequence, it sets its master time reference to the timing of the synchronization sequence. Since there is relative clock drift between the transmitters master time reference and the receivers master time reference, periodic resynchronization is usually required to ensure reliable data communications and low Bit Error Rates (BER).

In one embodiment of the present invention, extremely fast sampling of received signals is used to update the receiver's master time reference relative to the transmitter's master time reference. This enables less frequent re-synchronization and can eliminate the need for complex Phase Locked Loop (PLL) circuitry. The reduced need for re-synchronization also lowers overhead in the data stream and therefore increases overall data throughput of the communication system.

For example, as shown in FIG. 15, an electromagnetic pulse duration may have a duration of To, or alternatively, a “time bin” where an electromagnetic pulse may be located may have a duration of T₀. An extremely fast sampling array comprised of the cells and circuits described herein may have resolution of T₁. With these extremely fast sampling arrays, multiple signal samples may be obtained during time period T₀. For example, if the pulse duration is about 4 nano-seconds in duration, a 50 pico-second sampler could obtain 80 samples. As the electromagnetic pulses, or signals are detected at times that deviate from the master time reference of the receiver, the receiver time reference is updated.

As illustrated in FIG. 15, an electromagnetic pulse on line 10(a) arrives at the time the receiver expects. In 10(b) the pulse is delayed by two sampling periods. In 10(c) the receiver adjusts its master time reference from the drift present in 10(b) and the pulse is centered within the time period expected. In 10(d) shows another example of “clock drift,” and 10(e) shows a further correction of the receiver master time reference due to the drift in 10(d). Thus, the extremely fast sampling circuits, or cells of the present invention provide a method to correct relative deviations in master time references between transmitter and receiver without the need for resynchronization.

Referring now to FIG. 16, which illustrates an extremely fast sampling circuit according to one embodiment of the present invention. A Half Gilbert Multiplier circuit receives an input signal from a signal source, such as a receiver, antenna, or other suitable device. The Half Gilbert Multiplier multiplies the incoming current by a reference current. This resultant signal is proportional to the input signal to be sampled. Software Control Unit (SCU) sends a signal Su1 to the first switch SW1. Resistors R1 and R2 provide a path for current flow when switches SW1 and SW(fast) are in the open position. When a sample is desired of the incoming signal the SCU sends a Firing Signal to SW(fast), allowing current Iₜₒₜₐₗ to load resistor R_{Load} and capacitor, or other type of energy storage element C1. Current Iₜₒₜₐₗ, flowing across resistor R_{Load} and energy storage element C1, produces an output voltage Vout that is proportional to the signal being sampled. Energy storage element C1 additionally holds the value of Vout for a time period defined by (R_{Load})(C1).

Thus, it is seen that a system, method and article of manufacture are provided for arbitrary waveform generation suitable for communications in a wired or wireless medium. One skilled in the art will appreciate that the present invention can be practiced by other than the above-described embodiments, which are presented in this description for purposes of illustration and not of limitation. The description and examples set forth in this specification and associated drawings only set forth preferred embodiment(s) of the present invention. The specification and drawings are not intended to limit the exclusionary scope of this patent document. Many designs other than the above-described embodiments will fall within the literal and/or legal scope of the following claims, and the present invention is limited only by the claims that follow. It is noted that various equivalents for the particular embodiments discussed in this description may practice the invention as well.

1. A method of obtaining data from an electromagnetic signal, the method comprising the steps of:
receiving a modulated electromagnetic signal;
sampling the received signal; and
demodulating the signal without mixing the signal with a second electromagnetic signal.

2. The method of claim 1, wherein the step of sampling the signal comprises the step of:
providing an electromagnetic pulse sampling circuit; and
sampling the signal at a rate ranging between about 10 pico-seconds to about 500 pico-seconds.

3. The method of claim 1, wherein the step of sampling the signal comprises the step of:
providing a plurality of electromagnetic pulse sampling cells controlled by a digital computer; and
sampling the signal at a rate ranging between about 10 pico-seconds to about 500 pico-seconds.

4. The method of claim 1, wherein the step of demodulating the signal without mixing the signal with a second electromagnetic signal comprises:
comparing an amplitude of a later signal sample to an amplitude of a previous signal sample.

5. The method of claim 1, wherein the modulated signal is a communication signal selected from a group consisting of: a substantially continuous sinusoidal signal, a plurality of electromagnetic pulses, a plurality of ultra-wideband pulses, a sinusoidal carrier waveform, a spread spectrum signal, a multi-band ultra-wideband signal, an analog signal, and a digital signal.

6. The method of claim 3, wherein each of the plurality of ultra-wideband pulses has duration from about 10 picoseconds to about 100 milliseconds.

7. The method of claim 1, wherein the electromagnetic signal is obtained from a medium selected from a group consisting of: a wireless medium, and a wire medium.

8. A method of obtaining data from an electromagnetic signal, the method comprising the steps of:
receiving an electromagnetic signal containing data;
providing a plurality of electromagnetic pulse sampling cells; and
sampling the received signal; and
comparing an amplitude of a later signal sample to an amplitude of a previous signal sample.

9. The method of claim 8, wherein the step of sampling the received signal comprises sampling the received signal at a sample rate ranging between about 10 pico-seconds to about 500 pico-seconds.

10. The method of claim 8, wherein the received signal is a communication signal selected from a group consisting of: a substantially continuous sinusoidal signal, a plurality of electromagnetic pulses, a plurality of ultra-wideband pulses, a sinusoidal carrier waveform, a spread spectrum signal, a multi-band ultra-wideband signal, an analog signal, and a digital signal.

11. The method of claim 10, wherein each of the plurality of ultra-wideband pulses, or multi-band ultra-wideband pulses has duration from about 10 picoseconds to about 100 milliseconds.

12. The method of claim 8, wherein the electromagnetic signal is obtained from a medium selected from a group consisting of: a wireless medium, and a wire medium.

13. A method of maintaining an electromagnetic signal time reference, the method comprising the steps of:
receiving the electromagnetic signal having a first synchronization sequence;
setting a time reference based on the first synchronization sequence; and
updating the time reference before receiving a second synchronization sequence.

14. The method of claim 13, wherein the step of updating the time reference before receiving the second synchronization sequence comprises the steps of:
sampling the electromagnetic signal at least twice;
calculating a time reference drift of the received signal based on the two samples; and
shifting the time reference.

15. The method of claim 14, wherein the step of sampling the electromagnetic signal comprises sampling the electromagnetic signal at a sample rate ranging between about 10 pico-seconds to about 500 pico-seconds.

16. The method of claim 13, wherein the electromagnetic signal is a communication signal selected from a group consisting of: a substantially continuous sinusoidal signal, a plurality of electromagnetic pulses, a plurality of ultra-wideband pulses, a sinusoidal carrier waveform, a spread spectrum signal, a multi-band ultra-wideband signal, an analog signal, and a digital signal.

17. The method of claim 16, wherein each of the plurality of ultra-wideband pulses, or multi-band ultra-wideband pulses has duration from about 10 picoseconds to about 100 milliseconds.

18. The method of claim 13, wherein the electromagnetic signal is obtained from a medium selected from a group consisting of: a wireless medium, and a wire medium.

19. An electromagnetic pulse generating system comprising:
control means for generating a plurality of digital signals;
electromagnetic pulse generating means for generating a plurality of electromagnetic pulses in response to the plurality of digital signals; and
aggregating means for combining the plurality of electromagnetic pulses.

20. The electromagnetic pulse generating system of claim 19, wherein the aggregating means combines the plurality of electromagnetic pulses into a desired sinusoidal waveform or into a group of electromagnetic pulses.

21. The electromagnetic pulse generating system of claim 19, wherein the control means are selected from a group consisting of: a digital computer microprocessor controlled by computer logic, and a finite state machine.

22. The electromagnetic pulse generating system of claim 19, wherein the electromagnetic pulse generating means are connected in parallel.

23. The electromagnetic pulse generating system of claim 19, wherein the electromagnetic pulse generating means are connected in series.

24. The electromagnetic pulse generating system of claim 19, wherein the aggregating means is selected from a group consisting of: a summing circuit, and a multiplier.

25. A method of transmitting data, the method comprising the steps of:
receiving data for transmission;
modulating the data;
providing an electromagnetic pulse generating circuit;
generating a plurality of electromagnetic pulses arranged to represent the modulated data; and
transmitting the plurality of electromagnetic pulses.

26. The method of transmitting data of claim 25, wherein the step of generating a plurality of electromagnetic pulses comprises means for generating a plurality of electromagnetic pulses.

27. A method of obtaining data from an electromagnetic signal, the method comprising the steps of:
receiving a modulated electromagnetic signal;
means for sampling the received signal; and
means for demodulating the signal without mixing the signal with a second electromagnetic signal.
